(19) United States
(12) Patent Application Publication
(10) Pub. No.: US 2020/0305269 A1
(43) Pub. Date: Sep. 24, 2020

(54) Adhesive for Connecting a Power Electronic Assembly to a Heat Sink

(71) Applicant: Siemens Aktiengesellschaft, Muenchen (DE)

(72) Inventors: Florian Eder, Erlangen (DE); Sven Pihale, Stopfenheim (DE)

(73) Assignee: Siemens Aktiengesellschaft, Muenchen (DE)

(21) Appl. No.: 16/089,151

(22) PCT Filed: Feb. 21, 2017
(86) PCT No.: PCT/EP2017/053827

§ 371 Date: Sep. 27, 2018

(30) Foreign Application Priority Data
Mar. 30, 2016 (DE) 10 2016 205 178.4

(51) Int. Cl. H05K 1/02; C09J 183/08; B32B 7/12; B32B 15/04

(52) U.S. Cl. CPC H05K 1/0201; C09J 183/08; B32B 2307/302; B32B 15/04; B32B 2457/08; B32B 7/12

(57) ABSTRACT

Various embodiments include an adhesive for the heat-conducting joining of a ceramic substrate, especially of a power-electronic assembly, to a heat sink, and to an assembly composed of a heat sink and a ceramic substrate, made using this adhesive. The use of hybrid metal-organic compounds and/or waterglasses as adhesives produces high degrees of crosslinking and/or the formation of covalent bonds between the adhesive and the bond partners and/or the particles of filler produces a significant increase in the thermal conductivity, so that the thermally conductive layer of adhesive exhibits a greatly reduced thermal conduction resistance relative to the prior art, and so causes less of a load on the heat-removal chain than is normally the case with the conventional methods of joining and/or bonding.

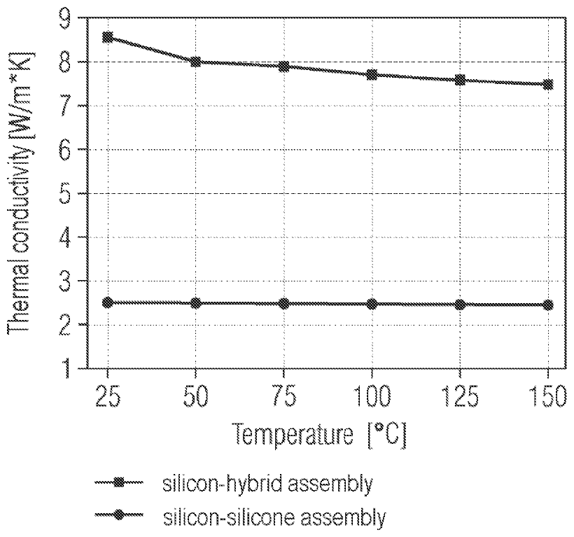

### CROSS-REFERENCE TO RELATED APPLICATIONS

This application is a U.S. National Stage Application of International Application No. PCT/EP2017/053827 filed Feb. 21, 2017, which designates the United States of America, and claims priority to DE Application No. 10 2016 205 178.4 filed Mar. 30, 2016, the contents of which are hereby incorporated by reference in their entirety.

### TECHNICAL FIELD

The present disclosure relates to adhesives. Various embodiments may include an adhesive for the heat-conducting joining of a ceramic substrate, e.g., a power-electronic assembly, to a heat sink, and/or an assembly of a heat sink with a ceramic substrate that is made using this adhesive.

### BACKGROUND

Printed-circuit boards with extensive metallic conductor-track structures, referred to here as power-electronic assemblies, are mounted, for the purpose of close electrical/thermal joining, on what are called DCBs (direct copper bonds). These bonds may comprise, for example, a ceramic substrate provided on both sides, or else in certain cases on one side, with metallization, as for example with copper and/or aluminum, or with an alloy. Because the electrical currents and/or powers switched by the power-electronic assemblies are generally high, electrical losses produce a large quantity of waste heat. This heat must be taken off, since otherwise the power-electronic assembly is no longer able to operate efficiently, or, in a worst-case scenario, is destroyed.

In order to prevent damage and/or destruction of the power-electronic assembly, highly loaded circuits are mounted on heat sinks, as for example metal blocks of aluminum, copper, alloys thereof, and/or heat-conductive alloys other than these. These heat sinks are themselves actively cooled, by means of a flow of cooling water through them, for example. To achieve efficient cooling of the power-electronic assemblies requires excellent thermal coupling of the ceramic substrate to the heat sink. This can be achieved by means of a material which affords not only high thermal conductivity but also low thermal transfer resistances to the contact surfaces.

Some examples of heat-conductive joining materials include metal layers which are applied in paste form and which solidify at temperatures well below the melting point of the metal to form dense, virtually pore-free structures, in a sintering operation, for example. An alternative possibility is to employ solders. This technique can no longer be employed, however, when using heat sinks which exceed a certain maximum size. The two bond partners—that is, ceramic substrate and cooling element—ought to be stable at the necessary operating temperatures, of 250° C. or more, for example, in order to allow the bond to be made. With large coolers, this entails very long heating times for a start. At the same time, however, after the bond has been completed, the power-electronic assembly remains at the high joining temperature for a comparatively long time, the reason being in particular that the heat sink acts as a heat store.

Generally speaking, the sintering processes referred to above take place with pressure exerted on the two bond partners (this operation being known as pressure sintering), in order to lower the operating temperature and operating time. Because the heat sinks often also comprise complex geometric structures, such as cooling fins, for example, the application of pressure entails increased cost and complexity in mass fabrication.

At the present time, DCBs are typically first applied to an assembly plate by means of soldering or sintering operations. The assembly plate is made, for example, of a heat-conductive metal or of a heat-conductive metal alloy, such as of aluminum, for example. Processing is simple, since the assembly plate is flat and has a low mass. For joining with the heat sink, a thermal paste is applied to the bottom face of the assembly plate and/or to the top face of the heat sink, and then the populated assembly plate—that is, for example, the DCB-aluminum plate—is bolted to the heat sink. The thermal conductivity of the thermal paste is better than that of air.

Some known adhesives are based on epoxide polymers in conjunction with thermally conductive particles, at high degrees of filling, that allow direct assembly of the DCBs with power-electronic assembly onto the heat sink, without the need to use an assembly plate. The thermal conductivity of the known adhesives, which cure typically at temperatures of around 100° C., is approximately 1 W/mK. The thermal conductivity of the metallization, such as of the copper and/or aluminum metallization, for example, however, is 300 to 400 times higher. It is therefore clear that, while this adhesive is able to reduce the cost and complexity of fabrication, it forms a major heat resistance in the heat-removal chain and thus its possibilities for use are therefore limited.

### SUMMARY

The teachings of the present disclosure may describe an adhesive which overcomes the disadvantages of the prior art and which in particular forms a lower heat resistance in the heat-removal chain. For example, some embodiments include an adhesive for joining an at least single-sidedly metallized ceramic substrate bearing a power-electronic assembly to a metallic heat sink, where the ceramic substrate bears on the heat sink and where the adhesive is such that with thermally conductive fillers optionally included, with the ceramic substrate surface to be joined and/or with the metallic surface of the heat sink, it forms at least in part covalent bonds.

In some embodiments, the noncrosslinked adhesive is based on a material from the class of compound of hybrid-organic metal oxides, more particularly of hybrid-organic transition-metal oxides, and also from the class of compound of waterglasses.

In some embodiments, the hybrid-organic metal oxide comprises, for example, an organic, i.e., carbon-containing, compound having an aluminum, zirconium, boron, titanium and/or silicon cation.

In some embodiments, the hybrid-organic metal oxide comprises at least one organic compound having a singly or multiply negatively charged radical which carries one or more organic functional and reactive groups selected from the following functional groups or substituents suitable for crosslinking: halogen (substituent), i.e., fluoro, chloro, bromo, iodo; pseudohalo, amino, amide, aldehyde, keto, carboxyl, thiol, hydroxyl, acryloyloxy, methacryloyloxy, epoxy, isocyanate, vinyl, ester, and ether group(s).

In some embodiments, the adhesive is based on a so-called waterglass, in other words a silicate-like and/or waterglass-like compound having structural elements such as —Si-0-Si—, —Al-0-Al—, —Si-0-Al—, —Si-0-Zr—, —Zr-0-Zr—, —Ti—O—Zr—, —Si-0-Ti—, —Al-0-Ti—, —Ti—O—Ti—, —Zr-0-Zr—, —Al-0-Ti— and/or —Al—O—Zr— bonds, and also on any desired copolymers, blends and/or mixtures of compounds which comprise these structural elements and/or of which the chemical properties are characterized by these structural elements.

In some embodiments, there are fillers present monomodally or multimodally.

As another example, some embodiments may include an assembly of a heat sink and a ceramic substrate, where the assembly is producible by bonding using an adhesive as described above.

### BRIEF DESCRIPTION OF THE DRAWINGS

The FIGURE shows a graph of the adhesives under comparison, on the one hand the conventional, prior-art silicon-silicone assembly, and an example assembly incorporating the teachings herein, with a silicon hybrid assembly.

### DETAILED DESCRIPTION

In general, an adhesive which on curing develops covalent bonds to the thermally conductive filler and/or to one or both bond partners overcomes at least some of the disadvantages of the prior art. A high degree of crosslinking of the adhesive brings about better thermal attachment and hence a lower heat resistance. Some embodiments include an adhesive for joining an at least single-sidedly metallized ceramic substrate bearing a power-electronic assembly to a metallic heat sink, where the ceramic substrate bears on the heat sink and where the adhesive is such that with thermally conductive fillers optionally included, with the ceramic substrate surface to be joined and/or with the metallic surface of the heat sink, it forms at least in part covalent bonds.

Some embodiments include an assembly of a heat sink and a ceramic substrate, the assembly being producible by bonding using an adhesive of the type specified at the outset.

In some embodiments, the noncrosslinked adhesive is from the class of compound of hybrid-organic metal oxides, especially of hybrid-organic transition-metal oxides, and/or from the class of compound of waterglasses, e.g. amorphous, water-soluble sodium, potassium, and/or lithium silicates which undergo silicification—a special form of crosslinking in the case of silicates or silicate-like metal oxides—to form water-insoluble assemblies.

A hybrid-organic metal oxide comprises, for example, an organic compound which comprises aluminum, zirconium, titanium, and/or silicon cations and functional, reactive groups which are suitable for crosslinking, such as aluminum sec-butoxide, for example.

In some embodiments, there is at least one organic compound present on a metallic central atom with at least one organic, singly or multiply negatively charged radical bonded in complex form and carrying one or more organic functional and reactive groups selected from the following reactive groups or substituents suitable for crosslinking: halogen (substituent), i.e., fluoro, chloro, bromo, iodo; pseudohalo, amino, amide, aldehyde, keto, carboxyl, thiol, hydroxyl, acryloyloxy, methacryloyloxy, epoxy, isocyanate, vinyl, ester, and ether group(s). In some embodiments, these organic and negatively charged radicals are bonded in complex form to a metallic center, such as, for example, to an aluminum, a titanium and/or a zirconium cation, and/or to a silicon atom. In the case of silicon, the adhesive then belongs, correspondingly, to the class of compound of silicon hybrid assemblies.

These compounds are obtainable, by example, through reaction of an organic fluoro, chloro, bromo, iodo, amino, amide, aldehyde, keto, carboxyl, thiol, hydroxyl, acryloyloxy, methacryloyloxy, epoxy, isocyanate, vinyl, ester, ether, sulfonic acid, phosphoric acid group(s), and/or of an organic compound carrying these or other electron-withdrawing substituents, with an aluminum, zirconium, titanium, and/or silicon hydroxide. In a condensation process, crosslinking then takes place between the multiply positive cation and the electronegative functional group, to form an oxygen-metal and/or halogen-metal bond which is predominantly covalent rather than predominantly ionic in character, owing to the organic and hence carbon-containing radicals on the oxygen and/or halogen.

On heating and/or on addition of acid, the crosslinking within the adhesive takes place by formation of predominantly covalent bonds to the metal cation. This bonding also corresponds to the joining of the adhesive to the surfaces of the filler particles, of the ceramic substrate, and of the metallic surface of the heat sink that are to be bonded.

In some embodiments, the reactive group of the adhesive, the group suitable for crosslinking, is selected from the group of the above-stated functional groups: halogen, fluoro, chloro, bromo, iodo, pseudohalo, amino, amide, aldehyde, keto, carboxyl, thiol, hydroxyl, acryloyloxy, methacryloyloxy, epoxy, cyanate, isocyanate, vinyl, ester, ether, sulfonic acid, phosphoric acid group(s).

In some embodiments, the metallic central atom is selected from the group of following elements: silicon, zirconium, aluminum, boron, titanium.

In some embodiments, the adhesive is based on a so-called waterglass, in other words a silicate-like and/or waterglass-like compound having structural elements such as —Si-0-Si—, —Al-0-Al—, —Si-0-Al—, —Si-0-Zr—, —Zr-0-Zr—, —Ti-0-Zr—, —Si-0-Ti—, —Al-0-Ti—, —Ti—O—Ti—, —Zr-0-Zr—, —Al-0-Ti— and/or —Al—O—Zr— bonds, and also on any desired copolymers, blends, and/or mixtures of compounds which comprise these structural elements and/or of which the chemical properties are characterized by these structural elements.

In some embodiments, there are additives and/or fillers, especially thermally conductive fillers. These may be present in multimodal form. For increasing the total thermal conductivity of the adhesive, these fillers may be present in degrees of filling of 20 vol % to 70 vol %, more particularly in degrees of filling of 30 vol % to 60 vol %, and/or in the range from 35 vol % to 55 vol %.

Employed as thermally conductive filler, for example, is a filler selected from the group of the metals of high thermal conductivity such as aluminum, copper, and iron, of ceramics and glasses such as silicon dioxide, alpha-alumina (Al₂O₃), titanate (TiO₂), and also comparable thermally conductive carbides and nitrides, such as boron nitride, for example. The fillers are employed in any desired particle morphology, as for example in platelet-shaped and/or spherical morphology. The filler can be employed in two plural fractions, multimodally, in relation to the material, the size and/or the morphology.

The particle size may be in the range from 10 nm to 20 μm, thus encompassing the entire range of nanoparticles and of microparticles. In some embodiments, there is at least one fraction having a particle size in the range from 100 nm to 15 μm and/or in the range from 500 nm to 10 μm.

On the basis of its high reactivity, in other words the capacity to form covalent bonds, to metallic and ceramic bond partners, an adhesive incorporating teachings of the present disclosure is as outstandingly capable of realizing comparatively low thermal transition resistances in the assembly and hence of achieving high thermal conductivities, where appropriate at correspondingly high degrees of filling. In some embodiments, for example, adhesives can be realized which in the assembly exhibit thermal conductivities of 4 W/mK and higher.

In some embodiments, there is no need for the assembly plate and/or a thermal paste requiring regular renewal. It is possible here, according to the particular application, for the use of an assembly plate or of an additional thermal paste to in fact be advisable, but no longer so mandatory as in accordance with the prior art.

As a working example for illustrating the invention, a bond was produced between a silicon wafer and a silicone. For this purpose, two Si wafer pieces each measuring 1×1 cm were coated with the corresponding materials, by means of a spin coating or immersion coating, for example, and immediately thereafter were bonded to one another with the aid of appropriate spacers. After thermal curing, the thermal conductivity of the assembly was ascertained in a single-layer measurement, and was compared with that of a silicone bond. In both cases, the thickness of adhesive was 25 μm and the overall assembly had a thickness of 0.6 mm.

Result:

In a temperature range of 25-150° C., the assembly with the exemplary adhesive displayed a thermal conductivity of 8.5-7.5 W/m*K. In comparison to this, the adhesively bonded assembly with the conventionally employed silicone had a thermal conductivity of 2.5-2.4 W/m*K for comparable adhesive-layer thickness or overall assembly layer thickness.

The FIGURE shows a graph of the adhesives under comparison, on the one hand the conventional, prior-art silicon-silicone assembly, and the assembly incorporating teachings of the present disclosure, with a silicon hybrid assembly. The silicon hybrid assembly has a significantly increased thermal conductivity of 8.6 W/mK by comparison with the silicon-silicone assembly, which displays a thermal conductivity of 2.5 W/mK in virtual independence of the temperature.

Working Example for the Production of an Adhesive:

0.05 mol of aluminum sec-butoxide was dissolved in ethyl acetoacetate. In parallel, 0.012 mol of aminopropyltrimethoxysilane was stirred into 0.15 mol of glycidoxypropyltrimethoxysilane. Solution 1 was then added and stirred for a further 60 minutes. Subsequently, HCl was added slowly dropwise with further cooling. The resulting solution was stirred with cooling (two hours) until the next day, and was used as an adhesive.

Curing of the Resultant Adhesive:

After the assembly has been produced, the adhesive is flashed off; this is followed by thermal curing.

What is claimed is:

1. An adhesive for joining a at metallized ceramic substrate bearing a power-electronic assembly to a heat sink, wherein the ceramic substrate bears on the heat sink, the adhesive comprising:
thermally conductive fillers; and
a noncrosslinked binder configured to form covalent bonds with the ceramic substrate surface t be and/or with a surface of the heat sink.

2. The adhesive as claimed in claim 1, wherein the noncrosslinked binder comprises a compound of hybrid-organic metal oxides and/or a waterglass.

3. The adhesive as claimed in claim 1, further comprising an organic compound having at least one cation selected from the group consisting of: aluminum, zirconium, boron, titanium, and silicon.

4. The adhesive as claimed in claim 1, further comprising an organic compound having a negatively charged radical which carries at least one organic functional and reactive group selected from the group consisting of: halogen (substituent), fluoro, chloro, bromo, iodo; pseudohalo, amino, amide, aldehyde, keto, carboxyl, thiol, hydroxyl, acryloyloxy, methacryloyloxy, epoxy, isocyanate, vinyl, ester, and ether group(s).

5. The adhesive as claimed in claim 1, wherein the binder comprises a compound having at least one structural element selected from the group consisting of: —Si-0-Si—, —Al-0-Al—, —Si-0-Al—, —Si-0-Zr—, —Zr—0-Zr—, —Ti—O—Zr—, —Si-0-Ti—, —Al-0-Ti—, —Ti—O—Ti—, —Zr-0-Zr—, —Al-0-Ti—, and —Al—O—Zr— bonds.

6. (canceled)

7. An assembly of a heat sink and a ceramic substrate, the assembly comprising:
a metallized ceramic substrate bearing a power-electronic assembly;
a heat sink; and
an adhesive joining the substrate and the heat sink, the adhesive comprising:
thermally conductive fillers; and
a noncrosslinked binder configured to form covalent bonds with the ceramic substrate surface and/or with a surface of the heat sink.
